(19) United States
(12) Patent Application Publication
(10) Pub. No.: US 2008/0107808 A1
(43) Pub. Date: May 8, 2008

(54) Method and an apparatus for the coating of a base body

(75) Inventors: Wolfram Beele, Hausen (CH); Michael Loch, Wehr (CH); Louis F. Pochet, Greensburg, PA (US); Beat Meyer, Anglikon (CH)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sulzer Metco AG, Wohlen (CH)

(21) Appl. No.: 11/890,598

(22) Filed: Aug. 6, 2007

(30) Foreign Application Priority Data
Aug. 8, 2006 (EP) 06118585.6

(51) Int. Cl. C23C 16/00; B05D 7/22

(52) U.S. Cl. 427/237; 118/728

(57) ABSTRACT

A method is proposed for coating a base body which has at lest one inner passage (101, 102), in which method the coating takes place by means of chemical deposition from the vapour phase, with the base body (10) being arranged on a holding device (3) in a reaction space (21) of a reactor vessel (2) with a process gas being delivered from an external source (7), the process gas being added to an internal generator (4) in the reaction container (2), in which the reactivity of the process gas is increased with the aid of a reactivity changing material and the process gas is conveyed out of the internal generator (4) into the reaction space (21). The process gas is sucked out of the reaction space (21) through the at least one inner passage (101, 102) and through the holding device (3) to an outlet (5) of the reactor vessel (2). Further an apparatus suitable for the method is proposed.

This application claims the priority of European Patent Application No. 06118585.6, filed Aug. 8, 2006, the disclosure of which is incorporated herein by reference.

The invention relates to a method and an apparatus for the coating of a base body which has at least one inner passage, with the coating taking place by means of chemical deposition from the vapour phase, in accordance with the pre-characterising part of the independent claim in the respective category.

In this special case the invention relates to a method and to an apparatus which are suitable to provide base bodies with complex inner structures, in particular turbine blades with cooling passages, with a preferably metallic coating.

During the operation of turbines which are used for example as engines for aeroplanes or as land-based industrial gas turbines, the aim is to realise as high a temperature as possible of the gas arising by means of the combustion, because the efficiency of the turbines is better the higher the temperature. Therefore it is usual, primarily in the high temperature region of the turbines, on the one hand, to select metallic compounds as a material which still possess very good mechanical characteristics even at very high temperatures and, on the other hand, to actively cool the workpieces such as, for example, the turbine blades by means of inner passages and/or to provide them with protective layers.

As a rule superalloys, which are usually nickel based or cobalt based alloys, are used as the material for the thermally most loaded workpieces of the turbines. These superalloys admittedly have an extraordinary strength at very high temperatures, however their characteristics with regard to the resistance to oxidation and resistance to hot corrosion are, however, often not sufficient in the aggressive atmosphere of the turbines. In order to solve this problem it is known to provide the superalloys with a layer which has a very good resistance to oxidation and resistance to hot corrosion.

For the production of hot corrosion resistant and hot oxidation resistant layers on base bodies made of superalloys it is known, for example, to use preferably metallic coatings, in particular aluminides. An alitierung (aluminisation) of the inner and outer surfaces of the base body is necessary to this end.

Above all the coating of the interior surfaces or of the interior cooling passages is not simple however. The inner structures are very complex in turbine blades and can usually only be reached through very narrow passages. On the other hand at the extremely high temperatures a coating of the inner passages is necessary because these would otherwise be oxidised rapidly in operation. Since the oxides arise in the narrow tortuous passages, as deposits they reduce the flow diameter for the cooling medium, by which means the efficiency of the cooling deteriorates. A worsening degradation process results from this.

There are some methods known for the coating, in particular for the aluminisation of such inner passages and passages, these have disadvantages however.

A known method is the pack cementation, in which the surfaces to be coated are embedded in a fine powder, which contains an aluminium source and also a volatile halide as a chemical transfer medium. The diffusion process usually takes place at temperatures of at least 700° C. The disadvantage of this process is that the powder can partly obstruct the passages or openings, so that the cooling air necessary for the operation of the turbine blades can later no longer or only inadequately flow through them.

A different method which is described in U.S. Pat. No. 4,132,816 for example, has become known by the term “over the pack process”. In this arrangement the parts to be coated are no longer embedded in the powder but rather are hung over the powder. Even if this method avoids the blocking of the passages by avoiding contact between the powder and the part to be coated, one observes here that the coating thickness at the entrances of the passages is larger and then reduces with increasing distance from the entrance. Moreover, the ratio of the coating thickness and concentration on the outer surfaces in comparison to the inner passages can only be checked with difficultly or not at all. Such irregular coatings can even render the turbine blades unusable.

In accordance with a modification of the method, which is described in U.S. Pat. No. 4,148,275, two chambers are provided in the reactor in order to simultaneously coat the interior and outer surfaces. The checking and reproducibility of the layer thickness is also problematic here.

A different method especially for the coating of inner passages is the chemical deposition from the vapour or gas phase (chemical vapour deposition: CVP) as is, for example, described in U.S. Pat. No. 5,264,245. The base body to be coated is placed in a reactor vessel. A gas containing aluminium is produced outside the reactor vessel, usually in that solid aluminium is caused to react with an activator gas, as a rule a halide. The aluminium halide gas is transported to the reactor vessel and improved in the reactor vessel with regard its reactivity. For example the less stable aluminium monochloride is generated from aluminium trichloride by suitable media, it has a higher relative proportion of aluminium and is more reactive. This gas is then brought into contact with the inner and outer surfaces of the base body whereby the alitising takes place. A separate gas inlet is provided for the coating of the interior surfaces through which the gas flows directly into the inner passages of the base body and is pushed through these into the reactor vessel from which it is then sucked off.

However this method is not yet satisfactory either with regard to the uniformity of the coating, in particular of the inner passages.

Starting from this prior art it is an object of the invention to propose a method and an apparatus for the coating of a base body having at least one inner passage, with as even a coating as possible being facilitated in particular of the interior surfaces or of the inner passages.

The subjects of the invention which satisfy this object apparatus-wise and method-wise are characterised by the features of the independent claims in the respective category.

In accordance with the invention a method is therefore proposed for the coating of a base body which has at least one inner passage in which method the coating takes place by means of chemical deposition from the vapour phase, with the base body being arranged on a holding device in a reaction space of a reactor vessel, wherein a process gas is delivered from an external source, the process gas is supplied to an internal generator in the reactor vessel in which the reactivity of the process gas is increased with the help of a reactivity changing material and the process gas is conveyed out of the internal generator into the reaction space. The process gas is sucked out of the reaction space through the at least one inner passage and through the holding device to an outlet of the reactor vessel.

It has surprisingly been shown that through the measure of bringing the process gas for the coating of the inner surface into the reaction space first and then sucking it out of this through the at least one inner passage, the inner surfaces in particular can be coated considerably more uniformly and efficiently.

The flow rate of the process gas through each inner passage is advantageously controlled by means of the geometry of the flow connection between the inner passage and the holding device. For this purpose the holding devices are so designed that they have apertures which are in flow connection with an inner passage. If these apertures are made smaller or larger, then the flow rate of the process gas—and consequently the dwell time of the process gas in the inner passage can be adjusted in a controlled fashion. In particular, if a plurality of passages of different dimensions (such as length, diameter, curvature etc.) is provided in the base body, the relative flow rates in the different passages can be influenced directly and in a controlled fashion through this measure. Thus, for example, restrictions can be provided in the holding device in order to adjust the flow rates through passages of different diameter in such a way that the same dwell times of the process gas result in the respective passages.

A further advantageous measure is that the reaction space is filled with helium and evacuated at least once prior to the coating. In this way disturbing residual air which would lead to undesired oxidation during coating, can be removed effectively from the reaction space.

In accordance with a preferred way of carrying out the method the coating process is an aluminium coating process.

The reactivity changing material is preferably liquid and in particular liquid aluminium. It has been shown that a considerably higher concentration of the material to be deposited can be produced in the process gas using liquid material, in particular liquid aluminium, which facilitates a more effective coating.

The base body can be a turbine blade in particular, i.e. the method in accordance with the invention is especially suitable for the coating of the outer and inner surfaces of turbine blades.

An apparatus is further proposed by the invention for the coating of a base body which has at least one inner passage in which the coating takes place by means of chemical deposition from the vapour phase, said apparatus having a reactor vessel with a reaction space in which a holding device is provided for receiving the base body, wherein an inner generator is provided in the reactor vessel, which is suitable to increase the reactivity of a process gas conveyable from an external source with the help of a reactivity changing material and which has an outlet for introducing the process gas into the reaction space. The holding device is connected to an outlet of the reactor vessel and is designed to receive the base body in such a way that the process gas can flow out of the reaction space through the at least one inner passage of the base body and the holding device to the outlet.

This apparatus is especially suitable for the method in accordance with the invention because it is designed in such a way that the process gas can be led away out of the reaction space through the at least one inner passage.

For the same reasons as those already given for the method in accordance with the invention, preferably the geometry of the flow connection between the inner passage and the holding device is designed in the apparatus for each inner passage in such a way that a pre-determinable flow rate of the process gas can be realised through the respective passage.

In a preferred embodiment the holding device is designed to receive at least one turbine blade.

A base body, in particular a turbine blade is proposed by the invention which is coated using a method in accordance with the invention or using an apparatus in accordance with the invention.

Further advantageous measures and preferred procedures result from the dependent claims.

In the following the invention will be explained more closely apparatus-wise and technically method-wise with the help of embodiments and with the help of the drawing. The schematic drawing shows:

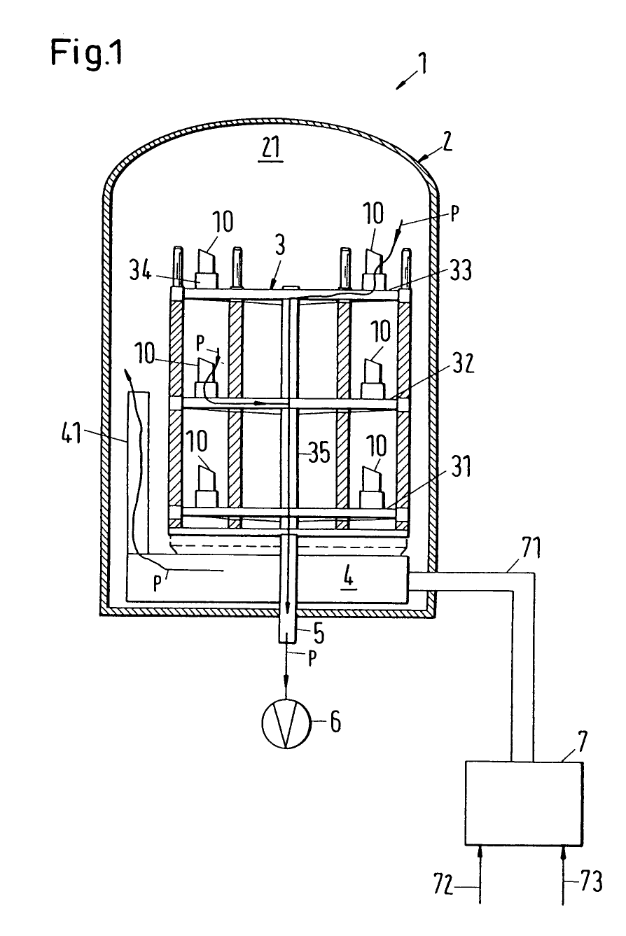

FIG. 1: a schematic illustration of important parts of an embodiment of an apparatus in accordance with the invention, which is suitable for carrying out a method in accordance with the invention and

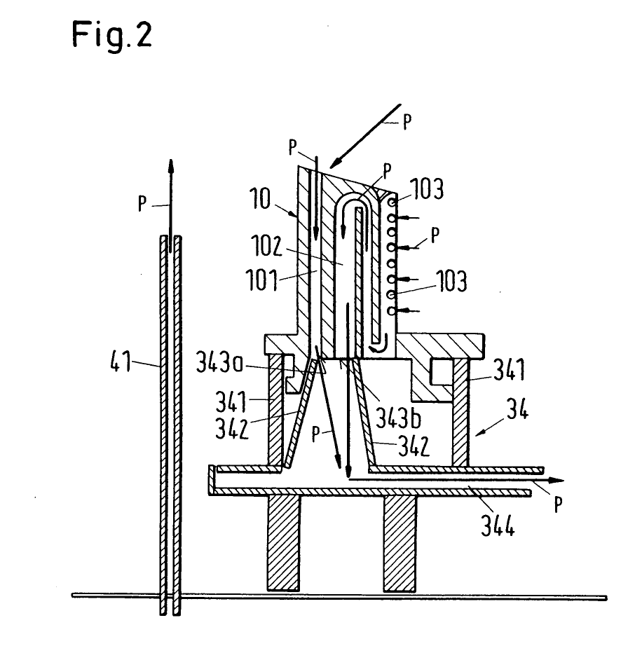

FIG. 2 an illustration of a turbine blade with inner passages which are received by the holding device.

A method and an apparatus is proposed by the invention for the coating of a base body 10 (FIG. 1) which has at least one inner passage. The coating takes place by means of chemical deposition from the vapour phase (chemical vapour deposition: CVP) using a process gas. CVP per se is a sufficiently known process the details of which will thus not be explained more closely here. In principle the method in accordance with the invention is suitable for all coatings, which can be manufactured by means of CVP, in particular for metallic coatings. It is possible, by means of the method in accordance with the invention, to coat inner surfaces and inner passages even with very complex structures with a pre-determinable thickness.

In the following reference will be made by way of example to the fact that the base body 10 to be coated is a turbine blade of an aircraft turbine or of a land-based industrial gas turbine. Reference will further be made to a case which is particularly important in practice that the outer and the inner surfaces of the turbine blade 10 are to be alitised (aluminised) i.e. that aluminium is to be chemically deposited from the vapour phase.

FIG. 1 shows in a schematic illustration an embodiment of an apparatus in accordance with the invention, which is designated throughout with the reference numeral 1. The apparatus 1 includes a reactor vessel 2 with a reaction space 21 in which a holding device 3 is arranged for receiving the base body, here a plurality of turbine blades 10. The holding device 3 usually includes a plurality of tiers, here three tiers 31, 32, 33, on which the turbine blades 10 are distributed.

An internal generator 4 is further provided in the reactor vessel 2 with which the reactivity of the process gas is increased for the CVP process. The internal generator has an outlet 41, through which the process gas is introduced from the internal generator into the reaction space 21. Otherwise the generator 4 is sealed relative to the reaction space 21.

The holding device 3 simultaneously serves to discharge the process gas and is designed as a gas collecting system. The holding device 3 has a holder 34 for each turbine blade 10 (FIG. 2) which is illustrated in more detail in FIG. 2.

In the embodiment illustrated in FIG. 2 the turbine blade 10 has two inner passages 101, 102 through which cooling air flows in the operating state. The inner passage 101 extends in a substantially straight line along the entry edge of the turbine blade 10. The inner passage 102 extends in tortuous manner from the outlet edge through the inside of the turbine blade 10. A plurality of cooling air bores 103 are provided at the outlet edge which open into the passage 102. In the operating state of the turbine the cooling air flows through the passage 102 and emerges through the cooling air bores 103.

The holder 34 for the turbine blade 10 has several functions. On the one hand the holder 34 retains the turbine blade 10 by means of a flange 341 adapted to the respective blade 10, with this flange 31 simultaneously serving to cover regions of the base body which are not to be coated, such as here the turbine blade foot. The holder 34 further has a gas passage 344 in its interior, through which the process gas can flow. Moreover, guide elements are arranged in the holder 34 which cooperate with the ends of the inner passages 101, 102 facing the holder 34 in such a way that they form flow connections 343a and 343b between the inner passages 101, 102 and the holding device 3, so that the process gas can flow out of the inner passages 101, 102 into the gas passage 344.

As FIG. 1 shows the gas passages 344 unite in a common conduit 35 of the holding device 3. This conduit 35 leads to an outlet 5 on the floor of the reactor vessel 2, which is connected to a pump 6. The pump 6 is a liquid ring pump or a mechanical vacuum pump for example. Designing the holding device 3 as a gas collection system makes an extremely compact and space saving design of the apparatus 1 in accordance with the invention possible.

Other components of the reactor vessel 2 known per se such as heating apparatuses, inlets and outlets for flushing the reaction space with argon etc. for example are known sufficiently from CVD technology and are therefore not explained in more detail here.

As FIG. 1 shows, an external source 7 is provided for the process gas which is connected to the internal generator 4 in the interior of the reactor vessel via a supply line 71. The starting materials are supplied to the external source 7—as indicated by the arrows 72 and 73—from which the process gas is generated. The source 7 can be a conventional generator for the production of a metal halide.

In the case of aluminisation a process gas containing aluminium halide is generated in the external source 7, for example aluminium trichloride AlCl₃ or aluminium trifluoride AlF₃. This can take place in a manner known per se by heating aluminium and then conducting corresponding acid halide gas over the heated aluminium. In the present case hydrochloric acid gas HCl is conveyed to the source 7 via the feed 72, in order to thus generate AlCl₃. A carrier gas can additionally be introduced via the feed 73, usually a reducing gas such as hydrogen H₂ and/or an inert gas such as argon Ar₂. This carrier gas then forms the process gas together with the AlCl₃, which is introduced via the feed line 71 into the internal generator 4 in the interior of the reactor vessel 2.

It is the object of the inner generator 4 to increase the reactivity of the process gas with the help of a reactivity changing material, in order to thus achieve a better deposition of the metal onto the surfaces to be coated. In the present case a considerable part of the aluminium chloride in the process gas is transformed into the aluminium richer and more reactive phase of the aluminium chloride AlC. Since AlCl is considerably more instable than AlCl₃, it is particularly advantageous that the aluminium richer phase AlCl is first produced in the interior of the reactor vessel 2. The process gas which now has a high proportion of AlCl, is then introduced from the inner generator 4 via its outlet 41 into the reaction space 21.

The increase of the reactivity of the process gas by means of generation of the aluminium rich aluminium chloride in the inner generator 4 takes place, by conveying the process gas coming out of the external source, which contains AlCl₃, over or through heated, aluminium containing material.

One possibility consists of providing one or more containers with chrome aluminium (CrAl) chips in the inner generator 4, which are initially heated to a temperature which is favourable for the desired reaction. The process gas is then fed over or through these CrAl chips to increase its reactivity.

Other aluminium alloys are naturally also suitable to increase the reactivity of the process gas.

In accordance with a particularly preferred method step liquid metal, here liquid aluminium is provided in the inner generator 4 to increase the reactivity of the process gas. The aluminium is heated to above the melting point in elementary form in one or more containers, so that it is present in the liquid phase. The process gas coming from the external source 7 is then conveyed over this liquid aluminium. In addition the process gas is then advantageously led in a serpentine or meandering path through the internal generator 4, in order to realise a take-up of aluminium through the process gas which is as intensive as possible. It has been shown that using liquid aluminium as a reactivity changing material, a particularly high proportion of AlCl can be generated in the process gas and thus a particularly favourable prerequisite for the desired deposition. In order to avoid undesired reactions of the liquid aluminium in the inner generator, the containers for the liquid aluminium are preferably made of graphite.

In the following an embodiment of the method in accordance with the invention will now be explained. Initially the base bodies—here the turbine blades 10—are inserted into the holders 34 of the holding device 3 which is matched to them. Then the reactor vessel is closed and flushed once or several times with an inert gas, for example argon, in particular to remove bothersome residues of air or oxygen which can lead to unwanted oxidations during coating. It has proved to be advantageous to additionally flush the reaction space 21 with helium at least once in order to safely remove air bubbles which can survive in particular in the upper region of the reaction space 21.

The turbine blades which are to be coated are heated to a temperature favourable for the reaction. The process gas is generated in the external source 7 and is fed to the inner generator 4. The reactivity of the process gas is increased there by means of liquid aluminium, with a considerable proportion of aluminium chloride AlCl being generated in the process gas. This process gas is introduced via the outlet 41 into the reaction space 21 where it disperses and the coating of the outer surfaces of the turbine blades 10 begins.

The process gas is sucked out of the reaction space 21 by means of the pump 6 through the cooling air bores 103 (FIG. 2) and through the inner passages 101, 102. In this process the coating of the inner surfaces and of the inner passages 101, 102 of the turbine blades 10 takes place. Finally, the process gas flows via the gas passages 344 and the common line 35 and the usually heated outlet 5 into not illustrated cooling/cryo traps and from there into likewise not illustrated neutralising containers.

The flow of the process gas is shown in FIG. 1 and FIG. 2 by the arrow with the reference letter P.

The coating procedure is carried out at a pressure between approximately 100 mbar and 1 bar in this embodiment. The process gas is heated to over 1000° C., for example 1080° C.

It is particularly advantageous to control the flow rate of the process gas and thus its dwell time in the inner passages 101, 102 by means of the geometry of the flow connections 343a, 343b between the inner passages 101, 102 and the holder of the holding device 3. Thus the relative flow rate of the process gas can be adjusted individually for each inner passage. Since the different inner passages 101, 102 often represent very different flow resistances, contingent on their length, their diameter or their curvature, for example, a situation can be achieved by appropriate dimensioning of the flow connections 343a, 343b in which the relative flow rates of the process gas adjust in such a way that a substantially uniformly thick coating is generated in the two inner passages 101, 102.

In this way system-related specific characteristics can also be taken into account. Thus it can happen that more process gas has a tendency to be sucked away through the lower tier 31 of the holding device 3 than through the upper tier 33. This can then be compensated for in that the flow resistance in the lower tier 31 is increased in such a way in comparison with the power resistance in the upper tier, by means of restrictions for example, that substantially the same relative flow rates and thus dwell times of the process gas result for corresponding inner passages of turbine blades 10 arranged on the lower tier 31 and on the upper tier 33. This adjusting of the flow resistance can take place both individually for each holder 34 and also in combination with an adjustment per tier 31, 32, 33.

For the cooling of the turbines blades 10, in particular of modern gas turbines, these turbine blades are often equipped with very complex inner surfaces which have a plurality of gas flow paths of different geometry, for example apertures, passages, circuits or chambers, so that extremely different gas flow characteristics result. The requirements in order to coat all these inner surfaces satisfactorily, can be very different. The gas flow characteristics can be analysed experimentally or theoretically, for example by determining the length, the area, the volume of the passage to be coated. In dependence on the desired thickness of the coating the relative process gas flow rate can then be calculated for each of the inner passages relative to the other inner passages. With the aid of such analyses these the process gas flow rates for each inner passage can be individually adjusted in such a way that the desired volume of process gas flows through this passage. The fine adjustment can then take place empirically.

As already mentioned, the adjusting of the respective flow rates through the inner passages preferably takes place by means of the apertures in the holder 34 or in the holding apparatus 3 being dimensioned in such a way that the desired relative flow rate of the process gas results.

It is naturally also possible to carry out the method in accordance with the invention by means of a corresponding adjustment of the relative flow rates in such a way that thicker or thinner coatings result in pre-determinable inner passages than in the other inner passages.

A method and an apparatus is thus proposed by the invention which also makes possible the coating of inner surfaces of hollow base bodies in particular, which have at least one inner passage. In addition the process gas is introduced into the reaction space 21 and then sucked out of the reaction space 21 through the at least one inner passage of the base body via a connection to the outlet of the reactor vessel. By this means a uniform coating of pre-determinable thickness can also be achieved on the inner surfaces.

1. A method for the coating of a base body, which has at least one inner passage (101, 102), in which method the coating takes place by means of chemical deposition from the vapour phase, with the base body (10) being arranged on a holding device (3) in a reaction space (21) of a reactor vessel (2), with a process gas being delivered from an external source (7), the process gas being supplied to an internal generator (4) in the reactor vessel (2), in which the reactivity of the process gas is increased with the help of an reactivity altering material and the process gas is conveyed out of the internal generator (4) into the reaction space (21), characterised in that the process gas is sucked out of the reaction space (21) through the at least one inner passage (101, 102) and through the holding device (3) to an outlet (5) of the reactor vessel (2).

2. A method in accordance with claim 1 in which the flow rate of the process gas through each inner passage (101, 102) is controlled by the geometry of the flow connection (343a, 343b) between the inner passage (101, 102) and the holding device (3).

3. A method in accordance with claim 1, which prior to the coating, the reaction space (21) is filled at least once with helium and evacuated.

4. A method in accordance with claim 1, which the coating process is an aluminium coating process.

5. A method in accordance with claim 1, with the reactivity changing material is liquid and is liquid aluminium in particular.

6. A method in accordance with claim 1, which the base body is a turbine blade (10).

7. An apparatus for the coating of a base body, which has at least one inner passage (101, 102) in which the coating takes place by means of chemical deposition from the vapour phase, said apparatus having a reactor vessel (2) with a reaction space (21) in which a holding device (3) is provided for receiving the base body (10), wherein an inner generator (4) is provided in the reactor vessel (2) which is suitable to increase the reactivity of a process gas which can be supplied from an external source (7) with the aid of a reactivity changing material and which has an outlet (41) for introducing the process gas into the reaction space (21), characterised in that the holding device (3) is connected to an outlet (5) of the reactor vessel (2) and is designed in such a way to receive the base body (10), that the process gas can flow out of reaction space (21) through the at least one inner passage (101, 102) of the base body (10) and the holding device (3) to the outlet (5).

8. An apparatus in accordance with claim 7, in which for each inner passage (101, 102) the geometry of the flow connection (343a, 343b) between the inner passage and the holding device is designed in such a way that a predeterminable flow rate of the process gas through the respective passage (101, 102) can be realised.

9. An apparatus in accordance with claim 1, which the holding device (3) is designed to receive at least one turbine blade (10).

10. A turbine blade, coated by using a method in accordance with claim 1.

11. A turbine blade coated by using an apparatus in accordance with claim 7.
